(19) United States
(12) Patent Application Publication
(10) Pub. No.: US 2005/0150452 A1
(43) Pub. Date: Jul. 14, 2005

(54) Process kit design for deposition chamber

(76) Inventors: Soovo Sen, Sunnyvale, CA (US); Mark A. Fodor, Los Gatos, CA (US); Martin J. Seamons, San Jose, CA (US); Priya Kulkarni, Santa Clara, CA (US); Visweswaren Sivaramakrishnan, Santa Clara, CA (US); Sudha Rathi, San Jose, CA (US); Tsutomu Shimayama, Sagamihara-Shi (JP); Thomas Nowak, Cupertino, CA (US); Wendy H. Yeh, Mountain View, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 10/757,021

(22) Filed: Jan. 14, 2004

(51) Int. Cl. C23C 16/00

(52) U.S. Cl. 118/715

(57) ABSTRACT

The present invention provides a process kit for a semiconductor processing chamber. The processing chamber is a vacuum processing chamber that includes a chamber body defining an interior processing region. The processing region receives a substrate for processing, and also supports equipment pieces of the process kit. The process kit includes a pumping liner configured to be placed within the processing region of the processing chamber, and a C-channel liner configured to be placed along an outer diameter of the pumping liner. The pumping liner and the C-channel liner have novel interlocking features designed to inhibit parasitic pumping of processing or cleaning gases from the processing region. The invention further provides a semiconductor processing chamber having an improved process kit, such as the kit described. In one arrangement, the chamber is a tandem processing chamber.

### BACKGROUND OF THE INVENTION

1. Field of the Invention

The present invention generally relates to semiconductor substrate processing systems. More specifically, the present invention relates to a deposition chamber for a semiconductor substrate processing system.

2. Description of the Related Art

Integrated circuits (IC) are manufactured by forming discrete semiconductor devices on a surface of a semiconductor substrate. An example of such a substrate is a silicon (Si) or silicon dioxide (SiO₂) wafer. Semiconductor devices are oftentimes manufactured on very large scales where thousands of micro-electronic devices (e.g., transistors, capacitors, and the like) are formed on a single substrate.

To interconnect the devices on a substrate, a multi-level network of interconnect structures is formed. Material is deposited on the substrate in layers and selectively removed in a series of controlled steps. In this way, various conductive layers are interconnected to one another to facilitate propagation of electronic signals.

One manner of depositing films in the semiconductor industry is known as chemical vapor deposition, or “CVD.” CVD may be used to deposit films of various kinds, including intrinsic and doped amorphous silicon, silicon oxide, silicon nitride, silicon oxynitride and the like. Semiconductor CVD processing is generally done in a vacuum chamber by heating precursor gases which dissociate and react to form the desired film. In order to deposit films at low temperatures and relatively high deposition rates, a plasma can be formed from the precursor gases in the chamber during deposition. Such processes are known as plasma enhanced chemical vapor deposition, or “PECVD.”

Reliable formation of high aspect ratio features with desired critical dimensions requires precise patterning and subsequent etching of the substrate. A technique sometimes used to form more precise patterns on substrates is photolithography. The technique generally involves the direction of light energy through a lens, or “reticle,” and onto the substrate. In conventional photolithographic processes, a photoresist material is first applied on a substrate layer to be etched. In the context of optical resists, the resist material is sensitive to radiation or “light energy,” such as ultraviolet or laser sources. The resist material preferably defines a polymer that is tuned to respond to the specific wavelength of light used, or to different exposing sources.

After the resist is deposited onto the substrate, the light source is actuated to emit ultraviolet (UV) light or low X-ray light, for example, directed at the resist-covered substrate. The selected light source chemically alters the composition of the photoresist material. However, the photoresist layer is only selectively exposed. In this respect, a photomask, or “reticle,” is positioned between the light source and the substrate being processed. The photomask is patterned to contain the desired configuration of features for the substrate. The patterned photomask allows light energy to pass therethrough in a precise pattern onto the substrate surface. The exposed underlying substrate material may then be etched to form patterned features in the substrate surface while the retained resist material remains as a protective coating for the unexposed underlying substrate material. In this manner, contacts, vias, or interconnects may be precisely formed.

Photoresist film may comprise various materials, such as silicon dioxide (SiO₂), silicon oxynitride (SiON), silicon nitride (Si₃N₄), and hafnium dioxide (HfO₂). Somewhat recently, an effective carbon-based film has been developed by Applied Materials, Inc. of Santa Clara, Calif. That film is known as Advanced Patterning Film™, or “APF.” APF™ generally comprises films of SiON and amorphous carbon, or “α-carbon.”

The carbon layer is generally deposited by plasma enhanced chemical vapor deposition (PECVD) of a gas mixture comprising a carbon source. The gas mixture may be formed from a carbon source that is a liquid precursor or a gaseous precursor. Preferably, the carbon source is a gaseous hydrocarbon. For example, the carbon source may be propylene (C₃H₆). The injection of C₃H₆ is accompanied by the generation of an RF plasma within the process chamber. The gas mixture may further comprise a carrier gas, such as helium (He) or Argon (Ar). The carbonaceous layer may be deposited to a thickness of between about 100 Å and about 20,000 Å, depending upon the application.

The process of depositing a carbon-based (or “organic”) film such as APF™ produces a carbon residue, particularly at high deposition rates, such as rates greater than 2,000 Å/min. In this respect, carbon is deposited not only on the substrate, but on the internal chamber body, the substrate support, and various kit parts, e.g., liners and showerhead, as well. During subsequent depositions, the film on the walls of the chamber body and other parts can crack or peel, causing contaminant particles to fall onto the substrate. This, in turn, causes damage to resistors, transistor, and other IC devices on the substrate.

To reduce contamination of wafer features, the PECVD chamber must be periodically cleaned to remove particulates between depositions. Cleaning is generally done by passing an etch gas between substrate processing operations into the emptied chamber. The etching plasma may be a fluorine-containing gas such as nitrogen trifluoride. In the context of carbon-based deposition, an oxygen species that is reactive with the carbon film deposited on the chamber wall and the various kit parts, e.g., the heater, the showerhead, liners, etc. may be employed. This is known as a “dry clean” operation.

Dry cleaning of a deposition chamber is generally effective in cleaning the chamber walls in an organic deposition chamber. However, oxygen in its reactive state is short-lived, and quickly recombines to an inactive state. This means that the oxygen plasma is less effective in reaching areas of the chamber apart from the primary flow path of the injected gases, i.e., the annular pressure ring, the heater area, etc. Therefore, it is necessary for the operator to periodically stop the substrate processing process altogether, and to disassemble the deposition chamber for scrubbing. This is known as a “wet clean” process.

When PECVD deposition chambers are silane or TEOS based, the wet-clean intervention process is rarely needed. However, in known carbon-based PECVD deposition chambers, the wet-clean intervention is required after every few hundred substrate processing cycles. It has been observed by the inventors herein that the problem of carbon residue on various fixtures within a processing chamber and on chamber walls is exacerbated by the phenomenon of “parasitic pumping.” This means that processing gases are accessing remote areas of the processing chamber, requiring periodic disassembling and scrubbing of chamber parts. This interruption of substrate processing represents an obstacle to throughput and profitability of the semiconductor fabrication process.

Therefore, it is desirable to have a deposition chamber that is constructed such that the frequency for wet-clean interventions is reduced. There is further a need for an improved process kit design that inhibits penetration of carbon and build-up of carbonaceous residue in areas that are difficult for etching plasma to effectively clean.

### SUMMARY OF THE INVENTION

The present invention provides a process kit for a semiconductor processing chamber. The processing chamber is a vacuum processing chamber that includes a chamber body defining an interior processing region. The process kit includes a pumping liner configured to be placed within the processing region of the processing chamber, and a C-channel liner configured to be placed along an outer diameter of the pumping liner. The pumping liner and the C-channel liner have interlocking features designed to inhibit parasitic pumping of processing or cleaning gases from the processing region.

In one embodiment, the pumping liner comprises a circumferential body, a plurality of pumping holes disposed along the pumping liner body, a shoulder circumferentially placed along an upper surface of the pumping liner body, and a lower lip disposed along a radial portion of a lower surface of the pumping liner body. In one embodiment, the C-channel liner comprises a circumferential body, an upper arm, a lower arm, a channel portion for receiving process gases, an upper lip circumferentially disposed along the upper arm, and a lower shoulder residing along a radial portion of the lower arm. The upper lip of the C-channel liner is configured to interlock with the shoulder of the pumping liner, while the lower shoulder of the C-channel liner is configured to interlock with the lower lip of the pumping liner.

The invention further provides a semiconductor processing chamber having an interlocking process kit, such as the kit described above. In one arrangement, the chamber is a tandem processing chamber. The chamber may also include an upper pumping port liner in fluid communication with the channel portion of the C-channel liner.

### DESCRIPTION OF THE DRAWINGS

So that the manner in which the above recited features of the present invention can be understood in detail, a more particular description of embodiments of the invention may be had by reference to the appended drawings. It is to be noted, however, that the appended drawings illustrate only typical embodiments of this invention and are, therefore, not to be considered limiting of its scope.

FIG. 1 provides a top view of an exemplary semiconductor processing system. The processing system includes pairs of deposition chambers that receive the process kits of the present invention.

FIG. 2 provides a cross-sectional view of an illustrative deposition chamber for comparison. The chamber of FIG. 2 is a twin or “tandem” chamber. However, it is understood that the process kits described herein may be used in a single chamber design.

FIG. 3 provides a partial cross-sectional view of a typical chamber body. The chamber body is depicted in a schematic manner for the purpose of demonstrating gas flow paths. Arrows depict primary gas flow and parasitic gas flow paths within the chamber.

FIG. 4 presents a perspective view of a portion of a deposition chamber. A chamber body is provided to define a substrate processing region, and for supporting various liners. A wafer slit valve is seen in the chamber body, providing a wafer pass-through slit.

FIG. 5 shows a cutaway, perspective view of the illustrative deposition chamber of FIG. 4. Visible in FIG. 5 is a top liner, or “pumping liner,” supported by a surrounding C-channel liner.

FIG. 6 shows the chamber body of FIG. 5, highlighting the two exposed areas from the cutaway view. These two cross-sectional areas are designated as area 6A and area 6B.

FIG. 6A provides an enlarged view of cross-sectional area 6A from FIG. 6. Similarly, FIG. 6B provides an enlarged view of cross-sectional area 6B. The top liner and supporting C-channel liner are seen in each figure.

FIG. 7 shows an exploded view of the chamber body portion of FIG. 4. In this view, various liners from a process kit, in one embodiment, can be more clearly identified.

### DESCRIPTION OF EMBODIMENTS OF THE INVENTION

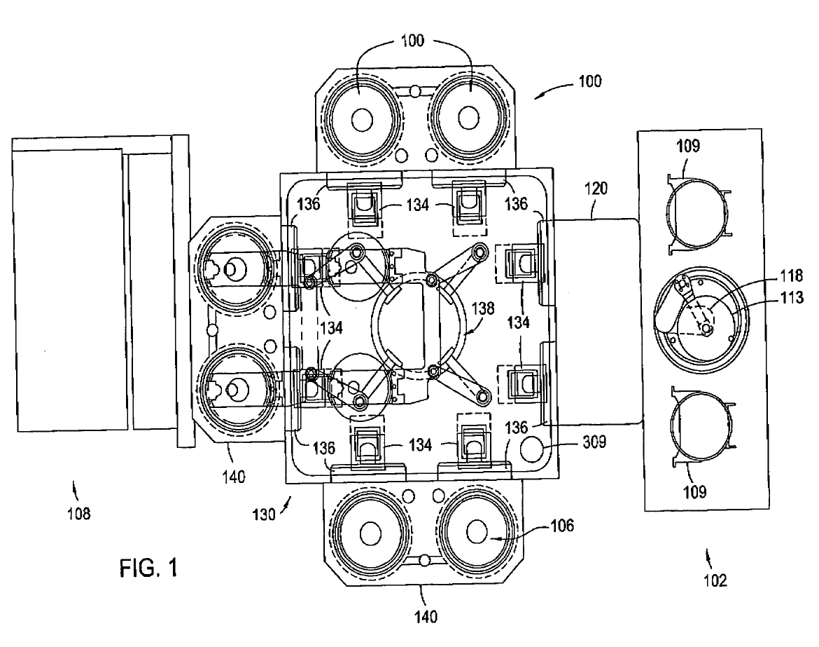

FIG. 1 provides a plan view of an exemplary semiconductor processing system 100. The processing system 100 includes processing chambers 106 that will receive the process kits of the present invention, described below. The illustrative chambers 106 are in pairs to further increase processing throughput.

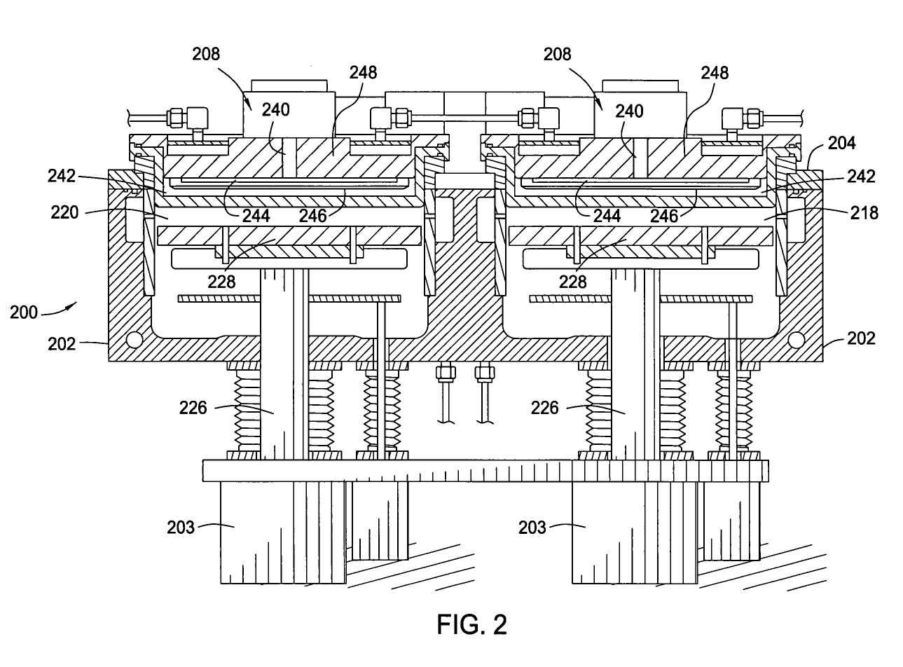

The system 100 generally includes multiple distinct regions. The first region is a front end staging area 102. The front end staging area 102 supports wafer cassettes 109 pending processing. The wafer cassettes 109, in turn, support substrates or wafers 113. A front end wafer handler 118, such as a robot, is mounted on a staging platform adjacent to wafer cassette turntables. Next, the system 100 includes a loadlock chamber 120. Wafers 113 are loaded into and unloaded from the loadlock chamber 120. Preferably, the front end wafer handler 118 includes a wafer mapping system to index the substrates 113 in each wafer cassette 109 in preparation for loading the substrates 113 into a loadlock cassette disposed in the loadlock chamber 120. Next, a transfer chamber 130 is provided. The transfer chamber 130 houses a wafer handler 136 that handles substrates 113 received from the loadlock chamber 120. The wafer handler 136 includes a robot assembly 138 mounted to the bottom of the transfer chamber 130. The wafer handler 136 delivers wafers through sealable passages 136. Slit valve actuators 134 actuate sealing mechanisms for the passages 136. The passages 136 mate with wafer passages 236 in process chambers 140 (shown in FIG. 2) to allow entry of substrates 113 into the processing regions for positioning on a wafer heater pedestal (shown at 228 in FIG. 2).

A back end 150 is provided for housing various support utilities (not shown) needed for operation of the system 100. Examples of such utilities include a gas panel, a power distribution panel, and power generators. The system can be adapted to accommodate various processes and supporting chamber hardware such as CVD, PVD and etch. The embodiment described below will be directed to a system employing a 300 mm APF deposition chamber. However, it is to be understood that other processes and chamber configurations are contemplated by the present invention.

FIG. 2 presents a cross-sectional, schematic diagram of a deposition chamber 200 for comparison. The deposition chamber is a CVD chamber for depositing a carbon-based gaseous substance, such as a carbon-doped silicon oxide sublayer. This figure is based upon features of the Producer S® APF chamber currently manufactured by Applied Materials, Inc. The Producer® CVD chamber (200 mm or 300 mm) has two isolated processing regions that may be used to deposit carbon-doped silicon oxides and other materials. A chamber having two isolated processing regions is described in U.S. Pat. No. 5,855,681, which is incorporated by reference herein.

The chamber 200 has a body 202 that defines an inner chamber area. Separate processing regions 218 and 220 are provided Each chamber 218, 220 has a pedestal 228 for supporting a substrate (not seen) within the chamber 200. The pedestal 228 typically includes a heating element (not shown). Preferably, the pedestal 228 is movably disposed in each processing region 218, 220 by a stem 226 which extends through the bottom of the chamber body 202 where it is connected to a drive system 203. Internally movable lift pins (not shown) are preferably provided in the pedestal 228 to engage a lower surface of the substrate. Preferably, a support ring (not shown) is also provided above the pedestal 228. The support ring may be part of a multi-component substrate support assembly that includes a cover ring and a capture ring. The lift pins act on the ring to receive a substrate before processing, or to lift the substrate after deposition for transfer to the next station.

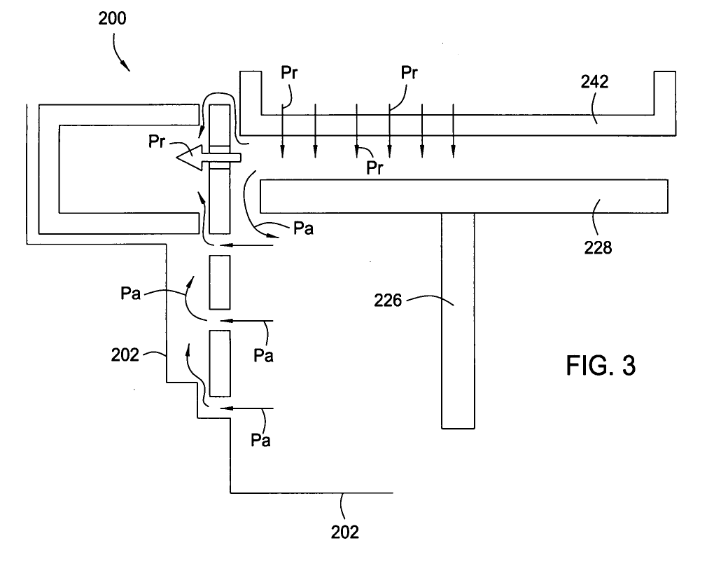

Each of the processing regions 218, 220 also preferably includes a gas distribution assembly 208 disposed through a chamber lid 204 to deliver gases into the processing regions 218, 220. The gas distribution assembly 208 of each processing region normally includes a gas inlet passage 240 which delivers gas into a shower head assembly 242. The showerhead assembly 242 is comprised of an annular base plate 248 having a blocker plate 244 disposed intermediate a face plate 246. The showerhead assembly 242 includes a plurality of nozzles (shown schematically at 248 in FIG. 3) through which gaseous mixtures are injected during processing. The nozzles 248 direct gas, e.g. propylene and argon, downward over a substrate, thereby depositing an amorphous carbon film. An RF (radio frequency) feedthrough provides a bias potential to the showerhead assembly 242 to facilitate generation of a plasma between the face plate 246 of the showerhead assembly 242 and the heater pedestal 228. During a plasma-enhanced chemical vapor deposition process, the pedestal 228 may serve as a cathode for generating the RF bias within the chamber walls 202. The cathode is electrically coupled to an electrode power supply to generate a capacitive electric field in the deposition chamber 200. Typically an RF voltage is applied to the cathode while the chamber body 202 is electrically grounded. Power applied to the pedestal 228 creates a substrate bias in the form of a negative voltage on the upper surface of the substrate. This negative voltage is used to attract ions from the plasma formed in the chamber 200 to the upper surface of the substrate. The capacitive electric field forms a bias which accelerates inductively formed plasma species toward the substrate to provide a more vertically oriented anisotropic filming of the substrate during deposition, and etching of the substrate during cleaning.

The gaseous hydrocarbon delivered through the showerhead assembly 242 is considered robust, and is able to flow throughout the chamber 200. FIG. 3 presents a partial cross-sectional view of the chamber body 202 of FIG. 2, in a schematic form. Arrows depict primary and parasitic gas flow paths within the chamber 200. The primary gas flow path is indicated by arrows Pr, while the parasitic gas flow path is indicated by arrows Pa. The primary gas flow path Pr is the preferred flow path, while the parasitic gas flow path Pa is undesirable. The parasitic gas flow Pa is able to contact various kit parts within the chamber 200, and to leak into unsealed areas. As noted above, periodic wet cleaning of the deposition chamber 200 is needed in order to access and sufficiently clean carbonic residue from the various parts and unsealed areas within the chamber 200.

The chamber of FIG. 3 is highly schematic. It will be understood by one of ordinary skill in the art from the drawing and from this disclosure that parasitic pumping may occur in gaps between the various liners and other hardware that make up a process kit for a processing chamber. Such areas susceptible to parasitic pumping include (1) the gap between a top liner and the faceplate; (2) the gap between a C-channel liner and the top liner; (3) the slit valve channel; (4) the gap between the C-channel liner and the middle liner at the slit valve tunnel; (5) the gap between the middle liner and the bottom liner; (6) the gap between a surrounding filler and the middle liner; and so forth.

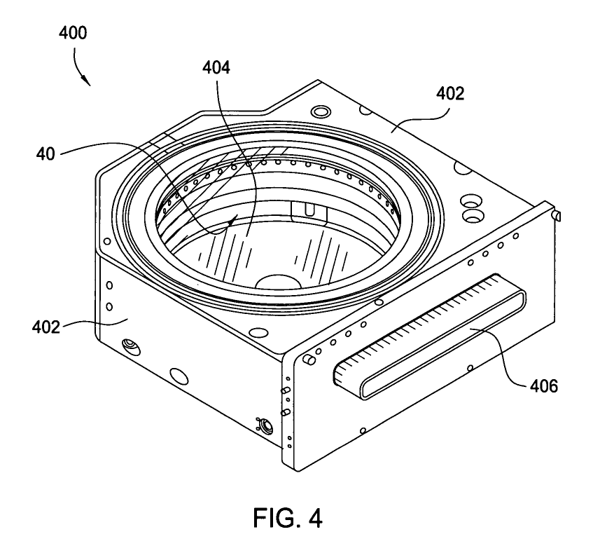

FIG. 4 presents a perspective view of a portion of a deposition chamber 400. The deposition chamber 400 includes a process kit 40 of the present invention, in one embodiment. A chamber body 402 is provided to define a substrate processing region 404, and for supporting various liners of the process kit 40. A wafer slit 406 is seen in the chamber body 402, defining a wafer pass through slit. In this manner, a substrate may be selectively moved into and out of the chamber 400. A substrate is not shown within the hollow chamber. The slit 406 is selectively opened and closed by a gate apparatus (not shown). The gate apparatus is supported by the chamber wall 402. The gate isolates the chamber environment during substrate processing.

The chamber body 402 is preferably fabricated from an aluminum oxide or other ceramic compound. Ceramic material is preferred due to its low thermal conductivity properties. The chamber body 402 may be cylindrical or other shape. The exemplary body 402 of FIG. 4 has an outer polygonal profile, and a circular inner diameter. However, the present invention is not limited to any particular configuration or size of processing chamber.

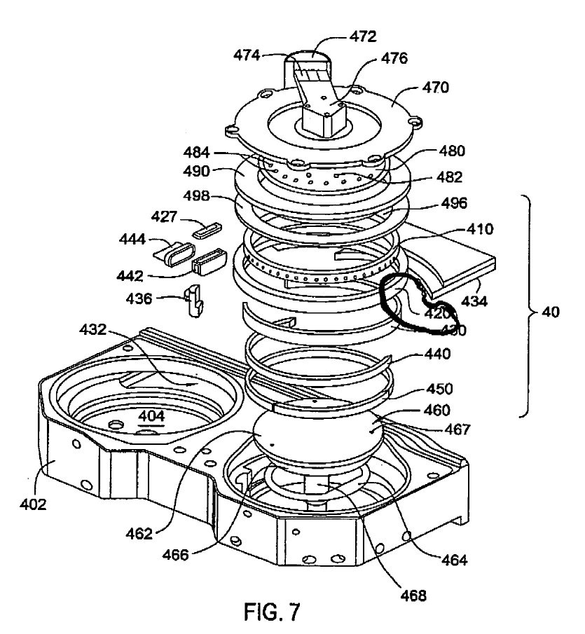

As noted, the body 402 is configured to support a series of liners and other interchangeable processing parts. These processing parts are generally disposable, and come as part of a “process kit” 40 specific for a particular chamber application or configuration. A process kit may include a top pumping liner, a middle liner, a lower liner, a gas distribution plate, a gas diffuser plate, a heater, a shower head, or other parts. Certain liners may be formed integrally; however, it is preferred in some applications to provide separate liners that are stacked together to allow thermal expansion between the liners. FIG. 7 provides a perspective view of a process kit 40 in one embodiment. The liners and other equipment of the process kit 40 are shown exploded above a deposition chamber 400. The chamber 400 of FIG. 7 will be discussed in greater detail below.

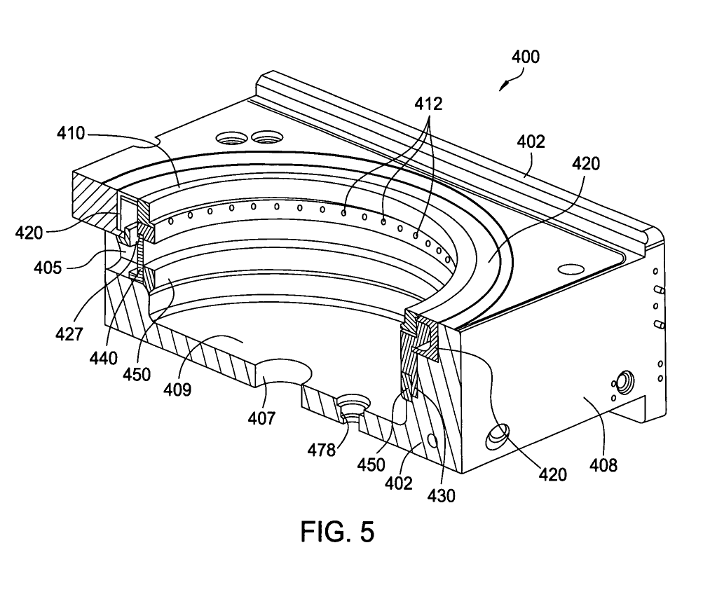

FIG. 5 shows a cutaway, perspective view of the illustrative deposition chamber 400 of FIG. 4. The geometry of the chamber body 402 is more clearly seen, including side 408 and bottom 409 portions of the body 402. An opening 405 is formed in the side portion 408 of the body 402. The opening 405 serves as a channel for receiving process gasses during a deposition, etching or cleaning process.

A substrate is not shown within the hollow chamber 404. However, it is understood that a substrate is supported within the hollow chamber 404 on a pedestal, such as pedestal 228 of FIG. 2. The pedestal is supported by a shaft that extends through opening 407 in the bottom portion 409 of the body 402. In addition, it is understood that a gas processing system (not shown in FIG. 5) is provided for the chamber 400. An opening 478 is provided in the illustrative chamber 400 for receiving a gas conduit. The conduit delivers gas to gas box (seen at 472 in FIG. 7). From there, gas is delivered into the chamber 404.

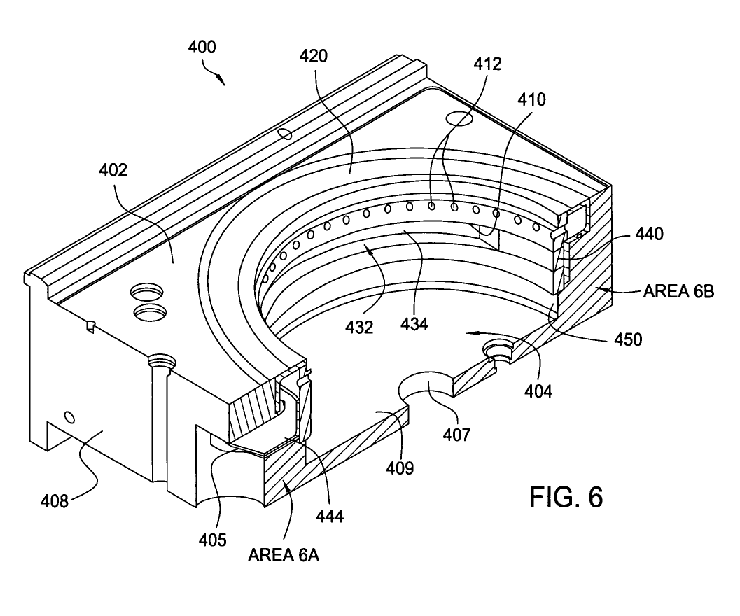

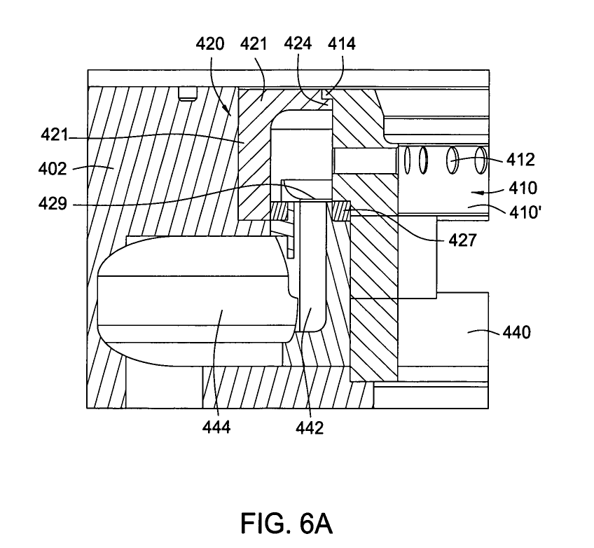

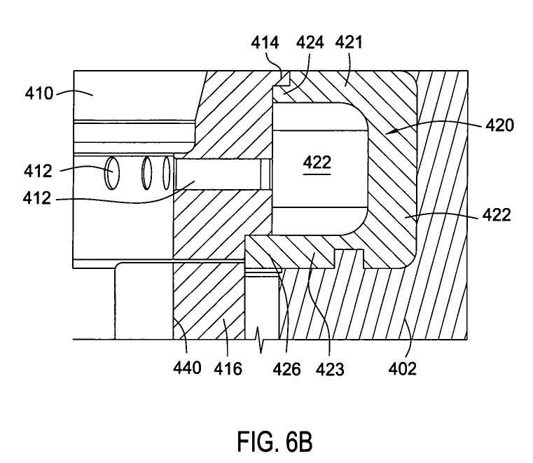

Certain parts of a process kit 40 for a deposition chamber are visible in FIGS. 4 and 5. These include a top pumping liner 410, a supporting C-channel liner 420, a middle liner 440 and a bottom liner 450. As noted, these liners 410, 420, 440 and 450 are shown and will be described in greater detail in connection with FIG. 7, below. A seal member 427 is provided at an interface of the C-channel liner 420 with a pumping port liner 442, and at an interface of the pumping liner 410 with the pumping port liner 442, as will be also shown and described in greater detail in connection with FIG. 6A, below.

FIG. 6 shows another perspective view of the chamber body 402 of FIG. 5. Reference numbers from FIG. 5 are, in some instances repeated. FIG. 6 is provided to highlight the two exposed areas from the cutaway view. These two cross-sectional areas are area 6A and area 6B. Features of the chamber 400 shown in areas 6A and 6B are seen more clearly in the respective enlarged cross-sectional views of FIGS. 6A and 6B. These features will also be described in detail below.

FIG. 7 provides an exploded view of a chamber body portion 400. In this instance, the chamber body 400 represents a tandem processing chamber. An example is the Producer S chamber manufactured by Applied Materials, Inc. Various parts of a process kit 40 are seen arising from the processing area 404 on the right side of the body 402.

The first item of equipment seen in the view of FIG. 7 is a top cover 470. The top cover 470 is centrally located within the processing area 404, and protrudes through the chamber lid (not seen). The top cover 470 serves as a plate to support certain gas delivery equipment. This equipment includes a gas box 472 which receives gas through a gas supply conduit (not seen). (The conduit is inserted through opening 478 in the bottom 409 of the chamber body 402, as seen in FIG. 5). The gas box 472 feeds gas into a gas input 476. The gas input 476 defines an arm that extends over to the center of the top cover 470. In this way, processing and cleaning gases may be introduced centrally into the processing area 404 above the substrate.

An RF power is supplied to the gas box 472. This serves to generate plasma from the processing gases. A constant voltage gradient 474 is disposed between the gas box 472 and the gas input 476. The constant voltage gradient 474, or “CVG,” controls the power level as the gas moves from the gas box 472 towards the grounded pedestal within the processing area 404.

Immediately below the top cover 470 is a blocker plate 480. The blocker plate 480 defines a plate concentrically placed below the top cover 470. The blocker plate 480 includes a plurality of bolt holes 482. The bolt holes 482 serve as a through-opening through which screws or other connectors may be placed for securing the blocker plate 480 to the top cover 470. A spacing is selected between the blocker plate 480 and the top cover 470. Gas is distributed in this spacing during processing, and then delivered through the blocker plate 480 by means of a plurality of perforations 484. In this way, processing gases may be evenly delivered into the processing area 404 of the chamber 400. The blocker plate 480 also provides a high pressure drop for gases as they are diffused.

Below the blocker plate 480 is a shower head 490. The shower head 490 is concentrically placed below the top cover 470. The shower head 490 includes a plurality of nozzles (not seen) for directing gases downward onto the substrate (not seen). A face plate 496 and isolator ring 498 are secured to the shower head 490. The isolator ring 490 electrically isolates the shower head 490 from the chamber body 402. The isolator ring 498 is preferably fabricated from a smooth and relatively heat resistant material, such as Teflon or ceramic.

Disposed below the shower head 490 is a top liner, or “pumping liner” 410. In the embodiment of FIG. 7, the pumping liner 410 defines a circumferential body having a plurality of pumping holes 412 disposed there around. In the arrangement of FIG. 7, the pumping poles 412 are equidistantly spaced apart. During a wafer processing process, a vacuum is pulled from a back side of the top liner 410, drawing gases through the pumping holes 412 and into a channel area 422 (seen more clearly in FIGS. 6A and 6B). The pumping holes 412 provide the primary flow path for processing gases, as depicted in the schematic view of FIG. 3.

Turning to the enlarged cross sectional views of FIGS. 6A and 6B, features of the top liner 410 can be more readily seen. FIG. 6A provides an enlarged view of cross-sectional area 6A from FIG. 6. Similarly, FIG. 6B provides an enlarged view of area 6B from FIG. 6. The pumping liner 410 is visible in each of these enlarged figures.

The pumping liner 410 defines a circumferential body 410′, and serves to hold a plurality of pumping ports 412. In the arrangement of FIG. 7, the pumping liner 410 includes an upper lip 414 on an upper surface area, and a lower shoulder 416 along a lower surface area. In one aspect, the upper lip 414 extends outwardly from the radius of the top liner 410, while the lower shoulder 416 extends radially inward. The upper lip 414 is circumferentially disposed. For this reason, the upper lip 414 is visible in both FIG. 6A and FIG. 6B. However, the lower shoulder 416 does not circumferentially encompass the top liner 410, but is left open in the area of an upper pumping port liner 442.

Returning to FIG. 4, the chamber 400 next comprises a circumferential channel liner 420. In the arrangement of FIG. 7, the liner 420 has a profile of an inverted “C”. In addition, the liner 420 includes a channel portion 422. For these reasons, the liner 420 is designated as a “C-channel liner.” The inverted “C” configuration is seen more clearly in the enlarged cross sectional view of FIG. 6B.

Looking again at FIG. 6B, the C-channel liner 420 has an upper arm 421, a lower arm 423, and an intermediate inner body 422. The upper arm 421 has an upper shoulder 424 formed therein. The upper shoulder 424 is configured to receive the upper lip 414 of the pumping liner 410. At the same time, the lower arm 423 is configured to receive the lower shoulder 416 of the top liner 410. This interlocking arrangement between the top liner 410 and the C-channel liner 420 provides a circuitous interface that substantially reduces unwanted parasitic pumping. In this way, as gases are exhausted from the processing area 404 of the chamber 400 and through the pumping holes 412 of the pumping liner 410, gas is preferentially evacuated through the channel portion 422 of the C-channel liner 420, and is not lost at the interfaces between the top liner 410 and the C-channel liner 420.

It is to be noted that the interlocking relationship between the upper lip 414 of the pumping liner 410 and the upper shoulder 424 of the C-channel liner 420 is illustrative only. Likewise, the interlocking relationship between the lower shoulder 416 of the pumping liner 410 and the lower lip 426 of the C-channel liner 420 is illustrative only. In this respect, it is within the scope of the present invention to include any interlocking arrangement between the pumping liner 410 and the C-channel liner 420 to inhibit parasitic pumping of processing, cleaning or etch gases. For example, and not by way of limitation, both the upper lip 414 and the lower shoulder 416 of the pumping liner 410 could be configured to extend outwardly from the radius of the top liner 410. In such an arrangement, the lower lip 426 of the C-channel liner 420 would be reconfigured to interlock with the lower shoulder 416 of the pumping liner 410.

In the process kit 40 arrangement of FIGS. 6A, 6B and 7, the upper shoulder 424 is circumferentially disposed along the upper arm 421. For this reason, the upper shoulder 424 is visible in both FIG. 6A and FIG. 6B. However, the lower lip 426 does not circumferentially encompass the C-channel liner 420, but is also left open in the area of the upper pumping port liner 442. Thus, a radial portion is left open to form a pumping port liner opening 429.

As indicated from the cutaway perspective view provided in FIG. 6, areas 6A and 6B show opposite ends of the chamber 400. The cutaway end from area 6A includes gas exhaust ports, referred to as “pumping port liners” 442, 444. An upper pumping port liner 442 is provided below the channel portion 422 of the C-channel liner 420. A lower pumping port liner 444 is then provided in fluid communication with the upper port liner 442. Gas may then be exhausted out of the lower pumping port liner 444 and away from the processing chamber 400 by means of an exhaust system.

To further limit parasitic pumping at the area of the pumping port liners 442, 444, a seal member 427 is provided at the interface between the C-channel liner 420 and the upper pumping port liner 442, and at the interface between the top liner 410 and the upper pumping port liner 442. The seal member is visible at 427 in both FIG. 7 and FIG. 6B. Preferably, the seal member 427 defines a circular ring that encompasses the upper pumping port liner 442. The seal member 427 is preferably fabricated from a Teflon material or otherwise includes a highly polished surface. The seal 427 further enables the C-channel liner 420 to interlock with the pumping ports 442, 444 and to limit gas leakage.

Referring back to FIG. 7, a middle liner 440 is next disposed below the C-channel liner 420. The middle liner 440 resides in the process area 404 at the level of the slit 432. It can be seen from FIG. 7 that the middle liner 440 is a C-shaped liner, and is not circular. The open area in the middle liner 440 is configured to receive wafers as they are imported into the process chamber 400. The middle liner 440 can be partially seen in both FIG. 6A and FIG. 6B, residing below the C-channel liner 420 and the top liner 410.

Also visible in FIG. 7 is a bottom liner 450. In the arrangement of FIG. 7, the bottom liner 450 is disposed in the chamber 400 below the middle liner 440. The bottom liner 450 resides between the middle liner 440 and the bottom surface 409 of the chamber 400.

It should be noted at this point that it is within the scope of the present invention to utilize a process kit wherein selected liners are integral to one another. For example, the middle liner 440 could be integrally formed with the bottom liner 450. Similarly, the top liner 410 could be integral to the C-channel liner 420. However, it again is preferred that the various liners, e.g., liners 410, 420, 440 and 450 be separate. This substantially reduces the risk of cracking induced by thermal expansion during heating processes. The employment of a separate but interlocking pumping liner 410 and C-channel liner 420 provides an improved and novel arrangement for a process chamber process kit.

Additional process kit items seen in FIG. 7 include a filler member 430 and a pressure equalization port liner 436. The filler member 430 is placed around the middle 440 and bottom 450 liners in order to fill space between the outer diameters of these liners 440, 450 and the surrounding chamber body 402. The presence of the filler member 430 aides in channeling the collection of carbon residues behind the liners 440, 450 by keeping residues from forming behind the liners 440, 450.

It is noted that the filler member 430, like the middle liner 440, is not completely circumferential. In this respect, an open portion is retained in the filler member 430 to provide fluid communication between the two process chambers 404. The pressure equalization port liner 436 controls the fluid communication between the two process areas 404 by defining a sized orifice. The presence of the pressure equalization port liner 436 insures that pressures between the two process areas 404 remain the same.

It is also noted at this point that the filler member 430, the pressure equalization port liner 436, and the upper 442 and lower 444 pumping port liners are preferably coated with a highly smoothed material. An example is a shiny aluminum coating. Other materials provided with a very smooth surface, e.g., less than 15 Ar help reduce deposition accumulating on the surfaces. Such smooth materials may be polished aluminum, polymer coating, Teflon, ceramics and quartz.

To further aide in the reduction of deposition on chamber parts, a slit valve liner 434 is provided along the slit 432. The slit liner 434 is likewise preferably fabricated from a highly smoothed material such as those mentioned above.

It is preferred that during a deposition or etching process, the processing areas 404 be heated. To this end, a heater is provided with the pedestal for supporting wafers. A heater pedestal is seen at 462 in the chamber arrangement 400 of FIG. 7. It is particularly preferred that the heater be actuated to temperatures in excess of 110° C. during a plasma cleaning process. Alternatively, it is possible to use ozone as the cleaning gas, as ozone does not require plasma to disassociate. In instances where ozone is not used, it is particularly desirable to heat the chamber body, thereby increasing the cleaning rate.

Referring again to FIG. 7, a pedestal assembly 460 is provided. The pedestal assembly 460 serves to support a substrate during processing. The pedestal assembly 460 includes not only the heater plate 462, but also a shaft 468, a pin lift 464 and a lift hoop 466 disposed there around. The pin lift 464 and lift hoop 466 aide in selectively raising the wafer above the heater plate 462. Pin holes 467 are disposed within the heater plate 462 to receive lift pins (not shown).

It is understood that the AFP™ chamber 400 of FIG. 7 is illustrative, and that the improvements of the present invention are viable in any deposition chamber capable of performing PECVD. Thus, other embodiments of the inventions may be provided. For example, the pumping liner 410 may have an inner diameter that is smaller than the inner diameter of the C-channel liner 420. This reduced dimension for the top pumping liner 410 serves to reduce the inner diameter of the pumping port 405, thereby increasing velocity of gases moving out of the inner chamber 404 and through the pumping port 405. Increased gas velocity is desirable, as it reduces opportunities for carbonaceous residue buildup on chamber surfaces. It is also desirable that the liners be fabricated from a material having a highly smooth surface. This serves to reduce amorphous carbon deposition from accumulating on the surface. Examples of such material again include polished aluminum, polymer coating, Teflon, ceramics, and quartz.

It is also noted that carbon builds up on colder surfaces faster than on warmer surfaces. Because of this phenomenon, carbon tends to preferentially build up on the pumping system associated with the deposition chamber. The pumping systems are preferably heated to a temperature greater than 80° C. to reduce preferential build-up. Alternatively, or in addition, a cold trap can be integrated into the pumping system to collect unreacted carbon by-product. The cold trap can be cleaned or replaced at regular maintenance intervals.

While the foregoing is directed to embodiments of the present invention, other and further embodiments of the invention may be devised without departing from the basic scope thereof. For example, one embodiment of a process kit for a vacuum processing chamber is provided, comprising a circumferential pumping liner configured to be placed within the processing region of a processing chamber, and a circumferential C-channel liner configured to be placed along an outer diameter of the pumping liner. The pumping liner may include a circumferential body having an upper surface and a lower surface, and a plurality of pumping holes disposed along the body. The C-channel may comprise a circumferential body portion having an upper surface and lower surface; a circumferential upper arm disposed proximate the upper surface of the body portion of the C-channel liner; a lower arm disposed around a selected radial portion of the body portion of the C-channel liner, the lower arm being along a bottom end of the body portion of the C-channel liner; and a channel portion in the C-channel liner defined between the body portion, the upper arm, the lower arm and an outer diameter of the pumping liner. An upper interlocking feature is provided between the upper surface of the pumping liner and the upper arm of the C-channel liner. Similarly, a lower interlocking feature is provided between the lower surface of the pumping liner and the lower surface of the C-channel liner. The upper and lower interlocking features serve to inhibit parasitic pumping within the processing region during processing of a wafer.

In one embodiment, the process kit is placed in a process chamber that includes a pumping port liner that is in fluid communication with a pumping port liner opening of the C-channel liner.

1. A process kit for a vacuum processing chamber, the vacuum processing chamber comprising a chamber body defining an interior processing region, the process kit comprising:
a pumping liner configured to be placed within the processing region of the processing chamber, the pumping liner comprising a circumferential body having an upper surface and a lower surface, wherein the body has a plurality of pumping holes disposed along the body; and
a C-channel liner configured to be placed along an outer diameter of the pumping liner, the C-channel liner comprising:
a circumferential body portion having an upper surface and lower surface,
a circumferential upper arm disposed proximate the upper surface of the body portion of the C-channel liner,
a lower arm disposed around a selected radial portion of the body portion of the C-channel liner, the lower arm disposed along the bottom surface of the body portion of the C-channel liner, and
a channel portion in the C-channel liner defined between the body portion of the C-channel liner, the upper arm, the lower arm, and an outer diameter of the pumping liner, wherein the C-channel liner has a pumping port liner opening;
wherein an upper interlocking feature is formed between the upper surface of the pumping liner and the upper arm of the C-channel liner;
wherein a lower interlocking feature is formed between the lower surface of the pumping liner and the lower arm of the C-channel liner; and
wherein the upper and lower interlocking features inhibit parasitic pumping within the processing region.

2. The process kit of claim 1, wherein the pumping liner is configured to rest on the C-channel liner.

3. The process kit of claim 1, wherein the upper interlocking feature comprises:
a shoulder circumferentially placed along the upper surface of the pumping liner body; and
an upper lip circumferentially disposed along the upper arm, the upper lip of the C-channel liner configured to interlock with the shoulder of the pumping liner body.

4. The process kit of claim 1, wherein the lower interlocking feature comprises:
a lower lip disposed along a radial portion of the lower surface of the pumping liner body; and
a lower shoulder along a radial portion of the lower arm, the lower shoulder of the C-channel liner configured to interlock with the lower lip of the pumping liner.

5. A process kit for a vacuum processing chamber, the vacuum processing chamber comprising a chamber body defining an interior processing region, the process kit comprising:
a pumping liner configured to be placed within the processing region of the processing chamber, the pumping liner comprising:
a circumferential body, wherein the circumferential body has a plurality of pumping holes disposed along the circumferential body,
a shoulder circumferentially placed along an upper surface of the pumping liner body, and
a lower lip disposed along a radial portion of a lower surface of the pumping liner body; and
a C-channel liner configured to be placed along an outer diameter of the pumping liner body within the processing region of the processing chamber, the C-channel liner comprising:
a circumferential body,
an upper arm,
a lower arm,
a channel portion defined by the upper arm, the lower arm, the body of the C-channel liner, and the body of the pumping liner,
an upper lip circumferentially disposed along the upper arm, the upper lip of the C-channel liner configured to interlock with the shoulder of the pumping liner body, and
a lower shoulder along a radial portion of the lower arm, the lower shoulder of the C-channel liner configured to interlock with the lower lip of the pumping liner and to also provide a pumping port liner opening.

6. The process kit of claim 5, further comprising:
a middle liner configured to reside below the pumping liner and the C-channel liner in the processing region.

7. The process kit of claim 6, further comprising:
a lower liner configured to reside below the middle liner in the processing region.

8. The vacuum processing chamber of claim 5, wherein the vacuum processing chamber further comprises a pumping port liner in fluid communication with the pumping port liner opening of the C-channel liner.

9. A vacuum processing chamber for processing a substrate, the vacuum processing chamber comprising a chamber body defining an interior processing region, and a process kit disposed within the processing chamber, the process kit comprising:
a pumping liner configured to be placed within the processing region of the processing chamber, the pumping liner comprising:
a circumferential body, wherein the circumferential body has a plurality of pumping holes disposed along the circumferential body,
a shoulder circumferentially placed along an upper surface of the pumping liner body, and
a lower lip disposed along a radial portion of a lower surface of the pumping liner body; and
a C-channel liner configured to be placed along an outer diameter of the pumping liner body within the processing region of the processing chamber, the C-channel liner comprising:
a circumferential body,
an upper arm,
a lower arm,
a channel portion defined by the upper arm, the lower arm, the body of the C-channel liner, and the body of the pumping liner,
an upper lip circumferentially disposed along the upper arm, the upper lip of the C-channel liner configured to interlock with the shoulder of the pumping liner, and
a lower shoulder along a radial portion of the lower arm, the lower shoulder of the C-channel liner configured to interlock with the lower lip of the pumping liner and to also provide a pumping port liner opening.

10. The vacuum processing chamber of claim 9, further comprising:
a pumping port liner in fluid communication with the pumping port liner opening of the C-channel liner.

11. The vacuum processing chamber of claim 10, further comprising:
a seal member providing a seal between
an interface of the C-channel liner with the pumping port liner, and
an interface of the pumping liner with the pumping port liner.

12. The vacuum processing chamber of claim 11, wherein the seal member has at least an outer surface fabricated from a material selected from the group consisting of a polished aluminum, a polymer coating, Teflon, ceramics, and quartz.

13. A tandem vacuum processing chamber for processing a substrate, the tandem vacuum processing chamber comprising:
a chamber body having a pair of interior processing regions provided within the chamber body, the interior processing regions being in fluid communication with one another; and
a process kit disposed within each of the interior processing regions, each process kit comprising:
a pumping liner configured to be placed within the respective processing region, the pumping liner comprising:
a circumferential body, wherein the circumferential body has a plurality of pumping holes disposed along the circumferential body,
a shoulder circumferentially placed along an upper surface of the pumping liner body, and
a lower lip disposed along a radial portion of a lower surface of the pumping liner body;
a C-channel liner configured to be placed along an outer diameter of the pumping liner body within the processing region, the C-channel liner comprising:
a circumferential body,
an upper arm,
a lower arm,
a channel portion defined by the upper arm, the lower arm, the body of the C-channel liner, and the body of the pumping liner,
an upper lip circumferentially disposed along the upper arm, the upper lip of the C-channel liner configured to interlock with the shoulder of the pumping liner, and
a lower shoulder along a radial portion of the lower arm, the lower shoulder of the C-channel liner configured to interlock with the lower lip of
the pumping liner and to also provide a pumping port liner opening; and
a pair of upper pumping port liners, each upper pumping port liner being in fluid communication with a respective pumping port liner opening.

14. The tandem vacuum processing chamber of claim 13, wherein the interior processing regions are maintained in fluid communication with one another through a pressure equalization port liner.

15. The tandem vacuum processing chamber of claim 14, wherein at least an outer surface of the pressure equalization port liner is fabricated from a smooth material selected from the group consisting of a polished aluminum, a polymer coating, Teflon, ceramics, and quartz.
